(19) United States
(12) Patent Application Publication
(10) Pub. No.: US 2026/0018861 A1
(43) Pub. Date: Jan. 15, 2026

(54) WAVELENGTH-TUNABLE LASER AND OPTICAL DEVICE

(71) Applicant: FURUKAWA ELECTRIC CO., LTD., Tokyo (JP)

(72) Inventors: Maiko ARIGA, Tokyo (JP); Kazuki YAMAOKA, Tokyo (JP)

(73) Assignee: FURUKAWA ELECTRIC CO., LTD., Tokyo (JP)

(21) Appl. No.: 19/330,430

(22) Filed: Sep. 16, 2025

Related U.S. Application Data
(63) Continuation of application No. PCT/JP2024/010378, filed on Mar. 15, 2024.

(30) Foreign Application Priority Data
Mar. 28, 2023 (JP) 2023-051665

(51) Int. Cl. H01S 5/06; H01S 5/00

(52) U.S. Cl. CPC H01S 5/0612; H01S 5/0078

(57) ABSTRACT

A wavelength-tunable laser includes: a light amplifying unit configured to emit light, amplify the light, and output the light from a first end portion and from a second end portion; a first mirror configured to reflect the light output from the first end portion; a second mirror configured to reflect the light output from the second end portion; an optical filter through which the light output from the light amplifying unit passes, the optical filter being disposed in between the light amplifying unit and one of the first mirror or the second mirror and having predetermined wavelength characteristics; a lens through which light travelling between the light amplifying unit and the optical filter passes, the lens being disposed in between the light amplifying unit and the optical filter; and a first temperature adjustment unit configured to adjust a temperature of the optical filter.

This application is a continuation of International Application No. PCT/JP2024/010378, filed on Mar. 15, 2024 which claims the benefit of priority of the prior Japanese Patent Application No. 2023-051665, filed on Mar. 28, 2023, the entire contents of which are incorporated herein by reference.

### BACKGROUND

The present disclosure relates to a wavelength-tunable laser and an optical device.

In the related art, a wavelength-tunable laser of the chip-integrated type is known (refer to Japanese Patent No. 2687464).

### SUMMARY

In the known wavelength-tunable laser, an amplifying unit that emits a light as well as amplifies the light is integrated with an optical filter that has predetermined wavelength characteristics.

In such a configuration, for example, when the amount of current to the amplifying unit is increased with the aim of enhancing the output of the laser, there is a risk that the heat generated in the amplifying unit reaches the optical filter and affects the wavelength characteristics of the optical filter.

There is a need for a wavelength-tunable laser and an optical device in a new and improved form that enable holding down the impact of the heat, which is generated in the amplifying unit, on the optical filter.

According to one aspect of the present disclosure, there is provided a wavelength-tunable laser including: a light amplifying unit configured to emit light, amplify the light, and output the light from a first end portion and from a second end portion on an opposite side of the first end portion; a first mirror configured to reflect the light output from the first end portion; a second mirror configured to reflect the light output from the second end portion; an optical filter through which the light output from the light amplifying unit passes, the optical filter being disposed in between the light amplifying unit and one of the first mirror or the second mirror and having predetermined wavelength characteristics; a lens through which light travelling between the light amplifying unit and the optical filter passes, the lens being disposed in between the light amplifying unit and the optical filter; and a first temperature adjustment unit configured to adjust a temperature of the optical filter.

### BRIEF DESCRIPTION OF THE DRAWINGS

FIG. 1 is an illustrative and schematic plan view illustrating a state in which an optical device according to a first embodiment has the upper lid thereof removed;

FIG. 2 is an illustrative and schematic plan view illustrating a state in which an optical device according to a second embodiment has the upper lid thereof removed;

FIG. 3 is an illustrative and schematic plan view illustrating a state in which an optical device according to a third embodiment has the upper lid thereof removed;

FIG. 4 is an illustrative and schematic plan view illustrating a state in which an optical device according to a fourth embodiment has the upper lid thereof removed;

FIG. 5 is an illustrative and schematic plan view illustrating a state in which an optical device according to a fifth embodiment has the upper lid thereof removed;

FIG. 6 is an illustrative and schematic plan view illustrating a state in which an optical device according to a sixth embodiment has the upper lid thereof removed;

FIG. 7 is an illustrative and schematic plan view illustrating a state in which an optical device according to a seventh embodiment has the upper lid thereof removed;

FIG. 8 is an illustrative and schematic side view of some portion of an optical device according to an eighth embodiment;

FIG. 9 is an illustrative and schematic side view of some portion of an optical device according to a ninth embodiment;

FIG. 10 is an illustrative and schematic side view of some portion of an optical device according to a 10th embodiment;

FIG. 11 is an illustrative and schematic side view of some portion of an optical device according to an 11th embodiment;

FIG. 12 is an illustrative and schematic side view of some portion of an optical device according to a 12th embodiment;

FIG. 13 is an illustrative and schematic plan view of an optical filter included in an optical device according to a 13th embodiment;

FIG. 14 is an illustrative and schematic side view of an optical filter included in an optical device according to a 14th embodiment;

FIG. 15 is an illustrative and schematic plan view of a heater included in an optical device according to a 15th embodiment;

FIG. 16 is an illustrative and schematic plan view of a heater included in an optical device according to a 16th embodiment;

FIG. 17 is an illustrative and schematic plan view of a heater included in an optical device according to a 17th embodiment;

FIG. 18 is an illustrative and schematic plan view of a heater included in an optical device according to an 18th embodiment; and

FIG. 19 is an illustrative and schematic plan view of a heater included in an optical device according to a 19th embodiment.

### DETAILED DESCRIPTION

Exemplary embodiments are described below. The configurations explained in the embodiments described below as well as the actions and the results (effects) attributed to the configurations are only exemplary. Thus, the present disclosure may be implemented also using some different configuration than the configurations disclosed in the embodiments described below. Meanwhile, according to the present disclosure, it becomes possible to achieve at least one of various effects (including secondary effects) that are attributed to the configurations.

The embodiments below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other.

### First Embodiment

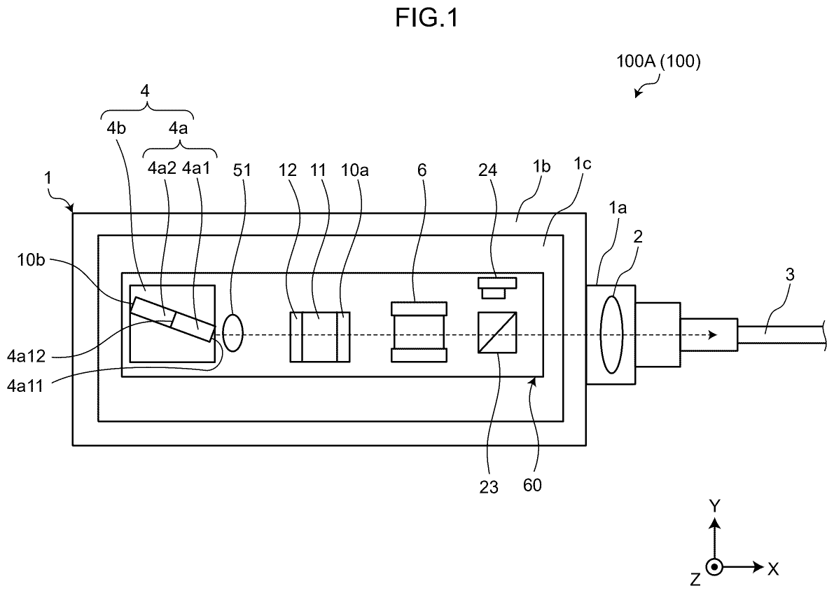

FIG. 1 is a plan view illustrating a state in which an optical module 100A (100) according to a first embodiment has the upper lid thereof removed. The optical module 100A (100) represents an example of an optical device that includes a wavelength-tunable laser.

As illustrated in FIG. 1, the optical module 100A includes a housing 1. The housing 1 includes an output port 1a, four sidewalls 1b, a bottom wall 1c, and an upper lid (not illustrated).

The bottom wall 1c is a plate-like member positioned at the end portion in the opposite direction to the Z direction. The bottom wall 1c intersects with the Z direction and is orthogonal to the Z direction, and extends in the X and Y directions with a substantially constant thickness in the Z direction. The bottom wall 1c is made of a material having high thermal conductivity, such as copper tungsten (CuW), copper molybdenum (CuMo), or aluminum oxide (Al₂O₃).

Each sidewall 1b is a plate-like member. Moreover, each sidewall 1b is substantially orthogonal to the bottom wall 1c, is orthogonal to the X and Y directions, and extends in the Z direction.

On the sidewall 1b that is positioned at the end portion in the X direction, the output port 1a is disposed. In the output port 1a, a lens 2 is housed. Moreover, the output port 1a supports an optical fiber 3 that outputs the output light to the outside.

The upper lid is a plate-like member positioned at the end portion in the Z direction. The upper lid intersects with the Z direction and is orthogonal to the Z direction, and extends in the X and Y directions with a substantially constant thickness in the Z direction. The upper lid is substantially parallel to the bottom wall 1c.

The output port 1a, the sidewalls 1b, and the upper lid are made of a material having a low thermal expansion coefficient, such as an Fe—Ni—Co alloy or aluminum oxide (Al₂O₃).

The chamber inside the housing 1 is, for example, sealed in an airtight manner. Inside the housing 1, for example, an inert gas such as the nitrogen gas may be filled. In that case, the nitrogen gas represents an example of a gaseous body.

The housing 1 has the following components housed therein: a chip-on-submount 4, a lens 51, a heater 12, an optical filter 11, a mirror 10a, an optical isolator 6, a beam splitter 23, a photodiode 24, and a carrier 60. Of those components, the chip-on-submount 4, the lens 51, the optical filter 11, the optical isolator 6, the beam splitter 23, and the photodiode 24 represent examples of an optical component. For example, an optical component is a component for outputting a light, or receiving a light, or transmitting a light, or imparting an action to a light. Meanwhile, inside the housing 1, other optical components other than the abovementioned components may also be housed; or components other than optical components, such as electronic components or electrical components, may also be housed.

In the first embodiment, the chip-on-submount 4, the lens 51, the heater 12, the optical filter 11, the mirror 10a, the optical isolator 6, the beam splitter 23, and the photodiode 24 are supported on the carrier 60 either directly or indirectly via some other members. The carrier 60 is, for example, a Peltier module equipped with the temperature adjustment function. In that case, the carrier 60 is capable of adjusting the temperature of a laser device 4a, and represents an example of a second temperature adjustment unit. Regarding a Peltier module, the detailed explanation is given later. Meanwhile, the second temperature adjustment unit for adjusting the temperature of the laser device 4a is not limited to a Peltier module. Alternatively, for example, it is possible to use a temperature adjustment module different than a Peltier module, such as a heater functioning as a resistance heating module.

The chip-on-submount 4 includes the laser device 4a and a submount 4b. The laser device 4a is a semiconductor laser device. The laser device 4a includes a light amplifying unit 4a1 and an optical filter 4a2. The chip-on-submount 4 may be referred to as a light emitting unit. The light amplifying unit 4a1 includes a laser medium such as a semiconductor active layer; and generates a light according to the applied electric current and amplifies that light. The light amplifying unit 4a1 outputs the light from one end portion 4a11 as well as from another end portion 4a12 that is on the opposite side of the end portion 4a11. The end portion 4a11 represents an example of a first end portion, and the end portion 4a12 represents an example of a second end portion.

The optical filter 4a2 has predetermined wavelength characteristics and enables passage of the lights having the wavelengths matching with those wavelength characteristics. The optical filter 4a2 is, for example, a Mach-Zehnder filter.

In the optical filter 4a2, at the end portion present on the opposite side of the light amplifying unit 4a1, a mirror 10b is disposed. The mirror 10b reflects at least some part of the incoming light. In the first embodiment, the mirror 10b reflects the light output from the optical filter 4a2, so that the reflected light is input to the optical filter 4a2. The mirror 10b is, for example, a dielectric multi-layer mirror. The mirror 10b represents an example of a second mirror. Meanwhile, when the optical filter 4a2 is, for example, a DBR filter (DBR stands for Distributed Bragg Reflector), the mirror 10b may be omitted from the configuration. In that case, the optical filter 4a2 doubles as a mirror (the second mirror).

The submount 4b supports the laser device 4a. The submount 4b is made of a material having high thermal conductivity and having insulating properties.

As illustrated by a dashed arrow in FIG. 1, the light that is output from the end portion 4a11 of the light amplifying unit 4a1 passes through the lens 51. The lens 51 is, for example, a collimated lens.

The light that has passed through the lens 51 reaches the mirror 10a via the heater 12 and the optical filter 11. The optical filter 11 has predetermined wavelength characteristics and allows passage of the lights having wavelengths matching with those wavelength characteristics. The optical filter 11 is, for example, an etalon filter.

The heater 12 is a resistive heater including a base member and a heat producing unit that produces heat due to the joule heat according to the supplied electric power. The heater 12 either has an opening formed therein for allowing passage of the light, or is made of a transparent material that allows passage of the light. Regarding the heater 12, the detailed explanation is given later. The heater 12 varies the optical path length of the optical filter 11, thereby enabling changing the wavelength characteristics of the optical filter 11. The heater 12 represents an example of a resistance heating module, and represents an example of a first temperature adjustment unit.

The mirror 10a reflects at least some part of the incoming light. In the first embodiment, the mirror 10a has appropriate light transmission characteristics and appropriate reflection characteristics; and reflects some part of the incoming light in such a way that the reflected light travels back to the optical filter 11, and allows passage of some part of the incoming light to the opposite side of the optical filter 11. The mirror 10a is, for example, a dielectric multi-layer mirror. The mirror 10a represents an example of a first mirror.

The optical isolator 6 allows passage of the incoming light toward the beam splitter 23, that is, in this case, allows passage of the light that has reached from the mirror 10a toward the beam splitter 23; as well as prevents the return of the light from the beam splitter 23.

The beam splitter 23 outputs the major part of the light to the lens 2 and outputs some part of the light to the photodiode 24. The lens 2 collects the light coming from the beam splitter 23 and couples the collected light in the optical fiber 3.

The photodiode 24 receives the light coming from the beam splitter 23, and outputs a detection signal according to the intensity of the received light. The detection signal is input to a controller via a wiring (not illustrated). Based on the detection signal received from the photodiode 24, the controller controls the operation of the laser device 4a.

In such a configuration, the light amplifying unit 4a1, the optical filter 4a2, and the optical filter 11 are present in between the mirrors 10a and 10b; and a resonance mechanism is configured in which the light travels back and forth and resonates at a predetermined wavelength in between the mirrors 10a and 10b. In the resonance mechanism, as a result of varying the temperatures of the optical filters 4a2 and 11 for varying their optical path lengths, the resonance wavelength may be varied.

In the first embodiment, since the lens 51 is disposed in between the laser device 4a and the optical filter 11, a longer distance may be maintained between the optical filter 11 and the light amplifying unit 4a1 of the laser device 4a. The light amplifying unit 4a1 produces heat during operation. Hence, in case the distance between the light amplifying unit 4a1 and the optical filter 11 is short, due to the heat produced in the light amplifying unit 4a1, accurate temperature adjustment of the optical filter 11 using the heater 12 is likely to become more difficult. In that regard, in the first embodiment, as a result of disposing the lens 51, it becomes possible to maintain a longer distance between the optical filter 11 and the light amplifying unit 4a1, and to hold down the impact of the heat on the optical filter 11 due to the light amplifying unit 4a1. As a result, it becomes possible to adjust the temperature of the optical filter 11 using the heater 12 with more accuracy.

In the first embodiment, the mirror 10a is disposed in the optical filter 11. Hence, for example, as compared to a configuration in which the mirror 10a is supported by another member other than the optical filter 11, it becomes possible to further simplify and downsize the configuration of the optical module 100. In turn, it becomes possible to reduce the time and efforts required in manufacturing the optical module 100.

### Second Embodiment

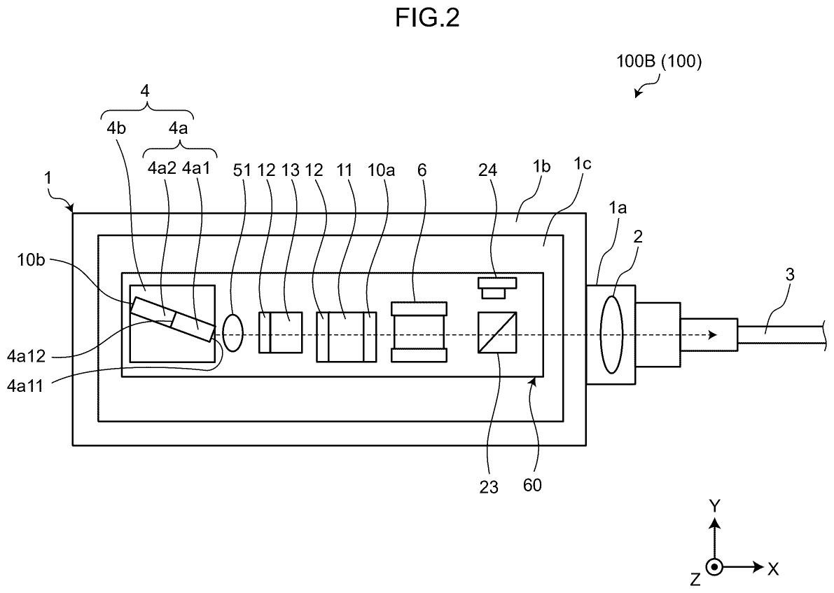

FIG. 2 is a plan view illustrating a state in which an optical module 100B (100) according to a second embodiment has the upper lid thereof removed. In the second embodiment too, the light amplifying unit 4a1, the optical filter 4a2, and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4a1 and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1.

Moreover, the optical module 100B according to the second embodiment includes a phase shifting filter 13 in between the lens 51 and the optical filter 11, and also includes the heater 12 that is capable of adjusting the temperature of the phase shifting filter 13. For example, the phase shifting filter 13 is a component made of a material, such as a glass block, that allows passage of the light emitted by the light amplifying unit 4al. When the temperature is adjusted by the heater 12, the phase shifting filter 13 becomes equipped with the function of varying the optical wavelength of the resonance mechanism.

According to such a configuration, because of the lens 51, it becomes possible to maintain a longer distance between the phase shifting filter 13 and the light amplifying unit 4a1 of the laser device 4a, and to hold down the impact of the heat on the optical filter 11 due to the light amplifying unit 4a1. As a result, it becomes possible to adjust the temperature of the phase shifting filter 13 using the heater 12 with more accuracy.

### Third Embodiment

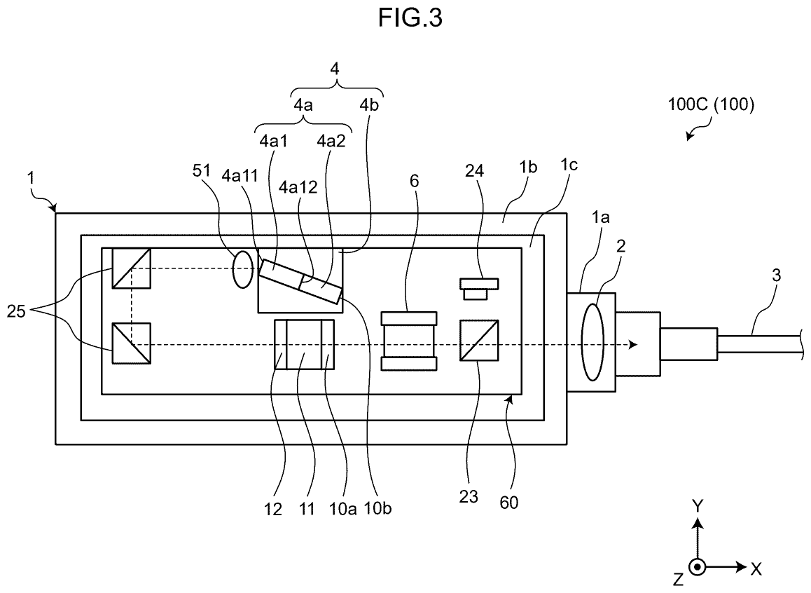

FIG. 3 is a plan view illustrating a state in which an optical module 100C (100) according to a third embodiment has the upper lid thereof removed. In the third embodiment too, the light amplifying unit 4a1, the optical filter 4a2, and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4a1 and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1.

However, in the optical module 100C according to the third embodiment, two beam reflectors 25 that reflect light are included in between the lens 51 and the optical filter 11. The beam reflectors 25 enable varying the direction of travel of the light or varying the position of travel of the light. The beam reflectors 25 may be called mirrors. The beam reflectors 25 represent examples of a first optical component.

According to such a configuration, since the beam reflectors 25 are included, for example, the optical filter 11 may be placed at a position at which there is less impact of the heat from the light amplifying unit 4a1, and the temperature adjustment of the optical filter 11 using the heater 12 may be performed with more accuracy. Moreover, the degree of freedom in the layout of the components inside the housing 1 may be enhanced.

### Fourth Embodiment

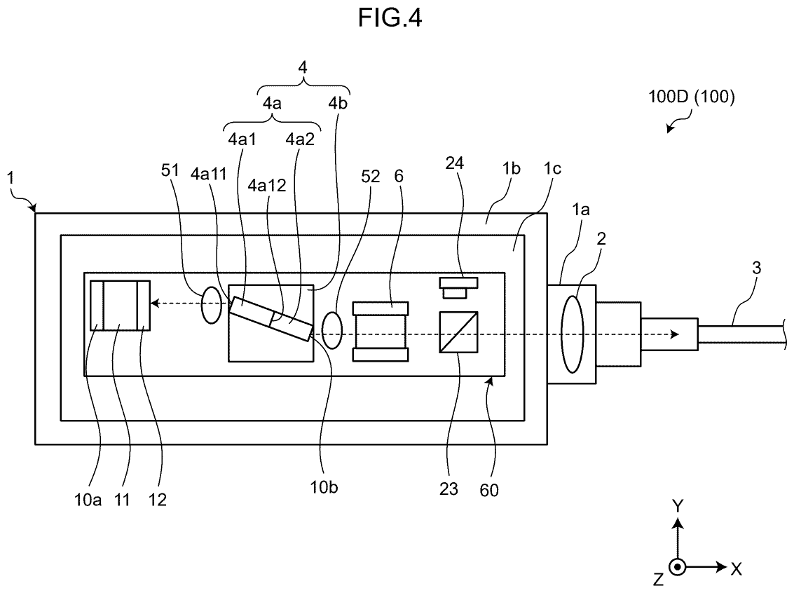

FIG. 4 is a plan view illustrating a state in which an optical module 100D (100) according to a fourth embodiment has the upper lid thereof removed. In the optical module 100D according to the fourth embodiment, the light that was output from the end portion 4a12 of the light amplifying unit 4a1 and that had passed through the optical filter 4a2 is input to the optical fiber 3 via a lens 52, the optical isolator 6, the beam splitter 23, and the lens 2. In that case, the light transmission characteristics and the reflection characteristics of the mirror 10b are adjusted in an appropriate manner. The lens 52 is, for example, a collimated lens. On the other hand, the light that is output from the end portion 4a11 of the light amplifying unit 4a1 reaches the mirror 10a via the lens 51, the heater 12, and the optical filter 11. The mirror 10a reflects the incoming light. In the fourth embodiment too, the light amplifying unit 4a1, the optical filter 4a2, and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4al and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1.

### Fifth Embodiment

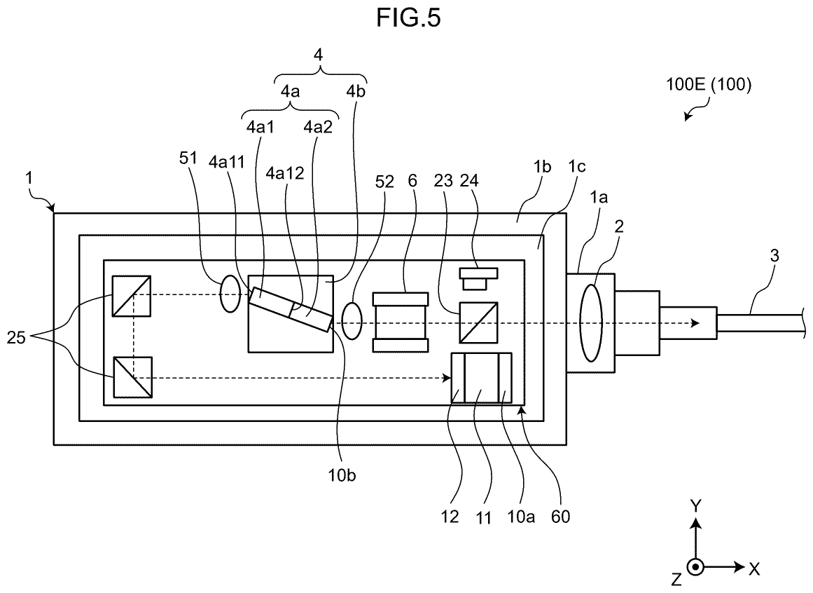

FIG. 5 is a plan view illustrating a state in which an optical module 100E (100) according to a fifth embodiment has the upper lid thereof removed. In the optical module 100E according to the fifth embodiment, the two beam reflectors 25 are disposed in between the lens 51 and the optical filter 11 of the optical module 100D according to the fourth embodiment. The beam reflectors 25 enable varying the direction of travel of the light or varying the position of travel of the light. The beam reflectors 25 may be called mirrors. The beam reflectors 25 represent examples of a first optical component. In the fifth embodiment too, the light amplifying unit 4a1, the optical filter 4a2, and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4a1 and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1.

Moreover, according to the fifth embodiment, since the beam reflectors 25 are included, the optical filter 11 may be placed at a position at which there is less impact of the heat from the light amplifying unit 4al, and the temperature adjustment of the optical filter 11 using the heater 12 may be performed with more accuracy. Moreover, the degree of freedom in the layout of the components inside the housing 1 may be enhanced.

### Sixth Embodiment

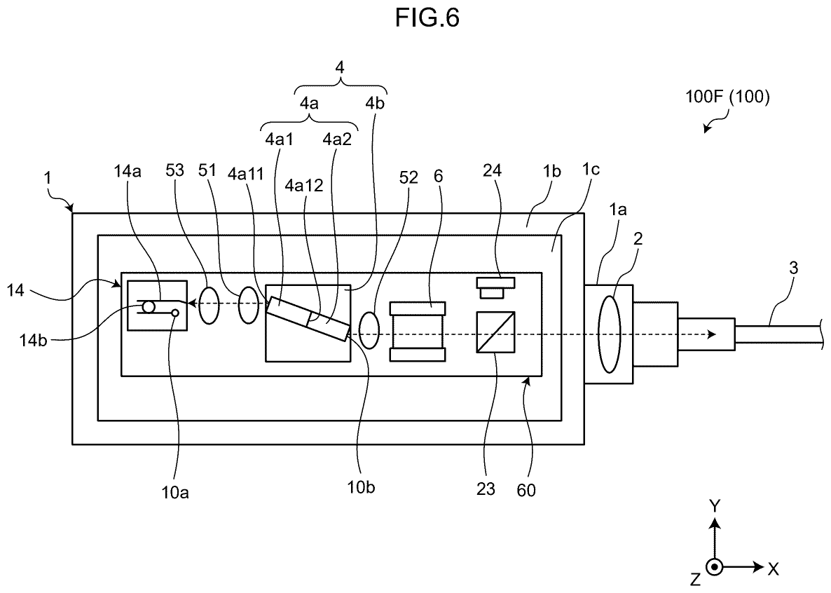

FIG. 6 is a plan view illustrating a state in which an optical module 100F (100) according to a sixth embodiment has the upper lid thereof removed. In the optical module 100F according to the sixth embodiment, a lens 53 and an optical semiconductor integrated device 14, which includes a waveguide 14a, are included in place of the heater 12, the optical filter 11, and the mirror 10a of the optical module 100D according to the fourth embodiment. The lens 53 is a condenser lens that optically connects the lens 51 and the optical semiconductor integrated device 14. The waveguide 14a includes a ring filter 14b having predetermined wavelength characteristics; includes the mirror 10a; and includes a heater (not illustrated) that locally heats the waveguide 14a. The ring filter 14b represents an example of an optical filter. However, the optical filter formed in the optical semiconductor integrated device 14 is not limited to a ring filter. Alternatively, for example, the optical filter may be a different type of filter such as a Mach-Zehnder filter. In the sixth embodiment, the light amplifying unit 4a1, the optical filter 4a2, and the ring filter 14b are present in between the mirrors 10a and 10b; and a resonance mechanism is configured in which the light travels back and forth and resonates at a predetermined wavelength in between the mirrors 10a and 10b. In the resonance mechanism, the lenses 51 and 53 are present in between the light amplifying unit 4a1 and the ring filter 14b, and accordingly a longer distance may be maintained between the light amplifying unit 4a1 and the optical semiconductor integrated device 14 including the ring filter 14b. Hence, it becomes possible to hold down the impact of the heat on the ring filter 14b due to the light amplifying unit 4a1.

### Seventh Embodiment

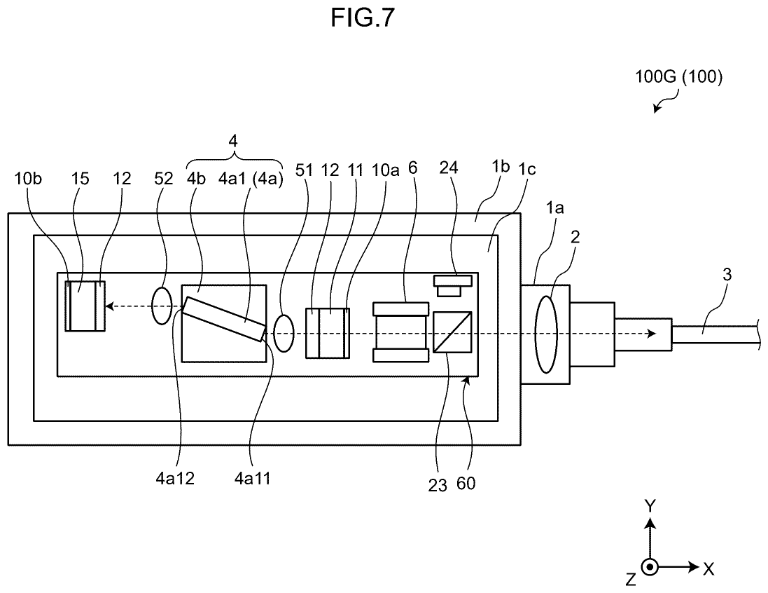

FIG. 7 is a plan view illustrating a state in which an optical module 100G (100) according to a seventh embodiment has the upper lid thereof removed. In the seventh embodiment, the laser device 4a includes only the light amplifying unit 4a1 without including the optical filter 4a2. In the optical module 100G, the lens 52, the heater 12, an optical filter 15, and the mirror 10b are included in place of the optical filter 4a2 of the optical module 100A according to the first embodiment. The light output from the end portion 4a12 of the light amplifying unit 4a1 reaches the mirror 10b via the lens 52, the heater 12, and the optical filter 15. In the seventh embodiment, the light amplifying unit 4a1, the optical filter 15, and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4al and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1. Moreover, the lens 52 is present in between the light amplifying unit 4a1 and the optical filter 15, and accordingly a longer distance may be maintained between the light amplifying unit 4al and the optical filter 15. Hence, it becomes possible to hold down the impact of the heat on the optical filter 15 due to the light amplifying unit 4a1. The optical filter 11 represents an example of a first optical filter, and the optical filter 15 represents an example of a second optical filter. The lens 51 represents an example of a first lens, and the lens 52 represents an example of a second lens.

### Eighth Embodiment

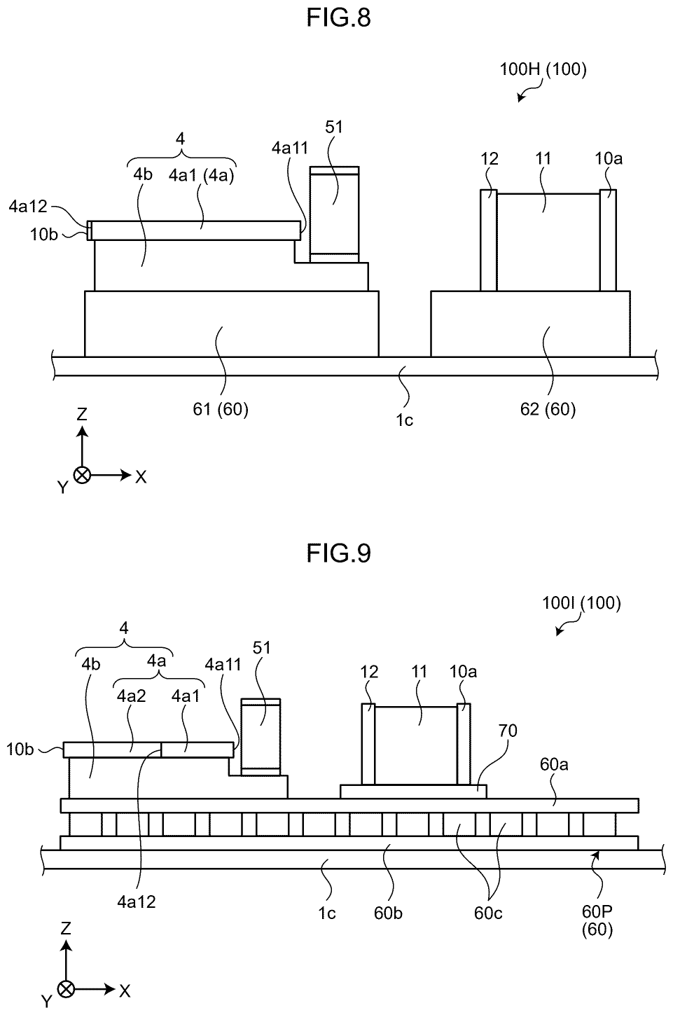

FIG. 8 is a side view of some portion of an optical module 100H (100) according to an eighth embodiment. In the optical module 100H according to the eighth embodiment, the lens 52, the heater 12, and the optical filter 15 of the optical module 100G according to the seventh embodiment are omitted, and the mirror 10b is disposed to abut against the end portion 4a12 of the light amplifying unit 4a1 of the laser device 4a. That is, the optical module 100H includes only a single optical filter 11. In the eighth embodiment, the light amplifying unit 4a1 and the optical filter 11 are present in between the mirrors 10a and 10b; and a resonance mechanism is configured in which the light travels back and forth and resonates at a predetermined wavelength in between the mirrors 10a and 10b. In the resonance mechanism, the lens 51 is present in between the light amplifying unit 4a1 and the optical filter 11, and accordingly a longer distance may be maintained between the light amplifying unit 4a1 and the optical filter 11. Hence, it becomes possible to hold down the impact of the heat on the optical filter 11 due to the light amplifying unit 4a1.

Moreover, in the eighth embodiment, the chip-on-submount 4, which includes the light amplifying unit 4a1, and the optical filter 11 are mounted on separate carriers 61 and 62 (60). Hence, according to the eighth embodiment, it becomes possible to hold down the heat transfer between the carriers 61 and 62, thereby further enabling holding down the impact of the heat on the optical filter 11 due to the light amplifying unit 4a1.

### Ninth Embodiment

FIG. 9 is a side view of some portion of an optical module 100I (100) according to a ninth embodiment. The optical module 100I according to the ninth embodiment has an identical configuration to the configuration of the optical module 100A according to the first embodiment.

In the ninth embodiment, the carrier 60 is configured as a Peltier module 60P. As illustrated in FIG. 9, the Peltier module 60P includes a first substrate 60a, a second substrate 60b, and a plurality of thermoelectric devices 60c. The thermoelectric devices 60c are columnar semiconductor devices disposed in between the first substrate 60a and the second substrate 60b. The thermoelectric devices 60c are made of P-type semiconductors or N-type semiconductors, such as bismuth telluride semiconductors. The thermoelectric devices 60c are connected in series in the state in which a P-N junction is formed due to the wiring pattern (not illustrated) disposed in between the first substrate 60a and the second substrate 60b. The circuit that includes the thermoelectric devices 60c, which are connected in series via the wiring pattern, is supplied with electric power from a wiring (not illustrated). As a result, depending on the orientation of the electric current of the electric power, the Peltier module 60P either absorbs heat or produces heat. The Peltier module 60P is capable of adjusting the temperature of the laser device 4a, and represents an example of a second temperature adjustment unit.

In the ninth embodiment, the optical filter 11, the heater 12, and the mirror 10b are supported on the Peltier module 60P via a heat shielding member 70. With such a configuration, it becomes possible to hold down the situation in which the accuracy of the temperature adjustment function of the heater 12 with respect to the optical filter 11 undergoes a decline due to the heat coming from the Peltier module 60P accompanying the temperature adjustment or due to the heat transmitted from the light amplifying unit 4a1 via the Peltier module 60P. The heat shielding member 70 represents an example of a first heat shielding member. The heat shielding member 70 is made of, for example, glass.

Along with the chip-on-submount 4 and the lens 51; the optical filter 11, the heater 12, and the mirror 10b are supported on the Peltier module 60P. With such a configuration, due to the temperature adjustment function of the Peltier module 60P, for example, it becomes possible to hold down the situation in which the relative positional relationship among the abovementioned optical components changes and the coupling efficiency among the optical components undergoes a decline.

### 10th Embodiment

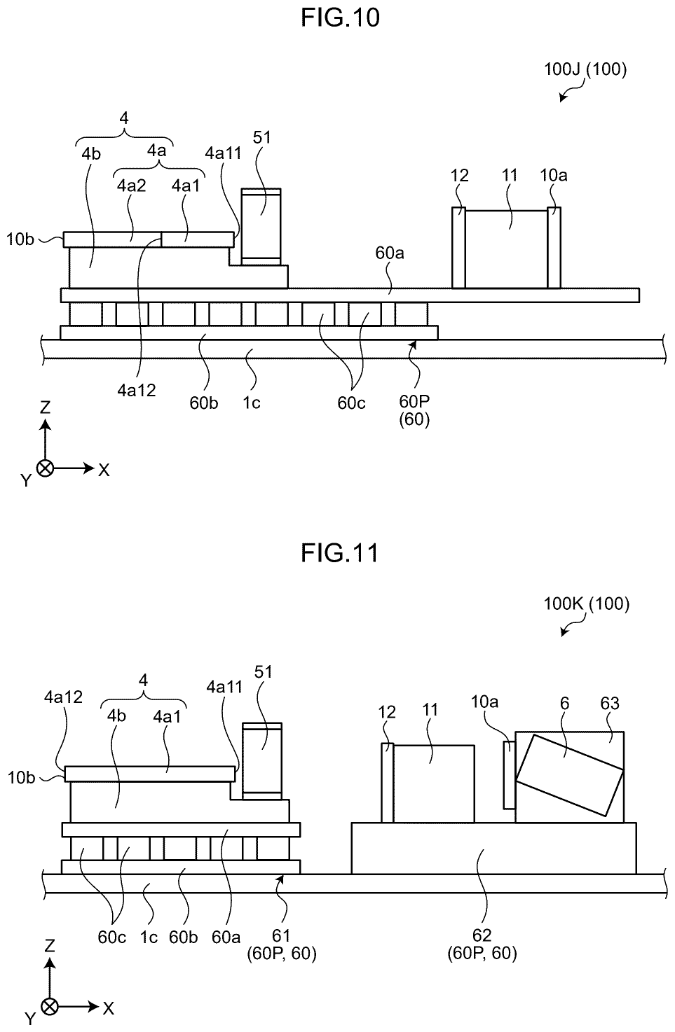

FIG. 10 is a side view of some portion of an optical module 100J (100) according to a 10th embodiment. The optical module 100J according to the 10th embodiment has an identical configuration to the configuration according to the optical module 100I according to the ninth embodiment. However, in the 10th embodiment, the optical filter 11 is more separated from the chip-on-submount 4 as compared to the configuration according to the ninth embodiment. Moreover, the optical filter 11 is supported in that region of the first substrate 60a in which the corresponding thermoelectric device 60c is absent and the temperature adjustment is not available.

With such a configuration, it becomes possible to hold down the situation in which the accuracy of the temperature adjustment function of the heater 12 with respect to the optical filter 11 undergoes a decline due to the heat coming from the Peltier module 60P accompanying the temperature adjustment or due to the heat transmitted from the light amplifying unit 4a1 via the Peltier module 60P. In the 10th embodiment too, in an identical manner to the ninth embodiment, the optical filter 11 may be supported on the first substrate 60a via the heat shielding member 70.

### 11th Embodiment

FIG. 11 is a side view of some portion of an optical module 100K (100) according to an 11th embodiment. The optical module 100K according to the 11th embodiment has an identical configuration to the configuration according to the eighth embodiment. Hence, according to the 11th embodiment too, it becomes possible to achieve identical effects to the effects achieved according to the eighth embodiment.

However, in the 11th embodiment, the mirror 10a that reflects the light, which has passed through the optical filter 11, is supported by a component 63 that is different than the optical filter 11. The component 63 supports the optical isolator 6 too. The component 63 is supported by the carrier 62. Meanwhile, instead of being supported by the component 63, the mirror 10a may be supported by the carrier 62 or by a part such as a protrusion formed on the bottom wall 1c of the housing 1, or may be supported by some other optical component.

With such a configuration, as compared to a configuration in which the mirror 10a and the optical isolator 6 are supported by separate components or parts, it becomes possible to further simplify and downsize the configuration.

The carrier 62 that supports the optical filter 11 may be the Peltier module 60P. In that case, the temperature adjustment of the optical filter 11 may be performed with a greater degree of accuracy. The Peltier module 60P functioning as the carrier 62 represents an example of a first temperature adjustment unit.

### 12th Embodiment

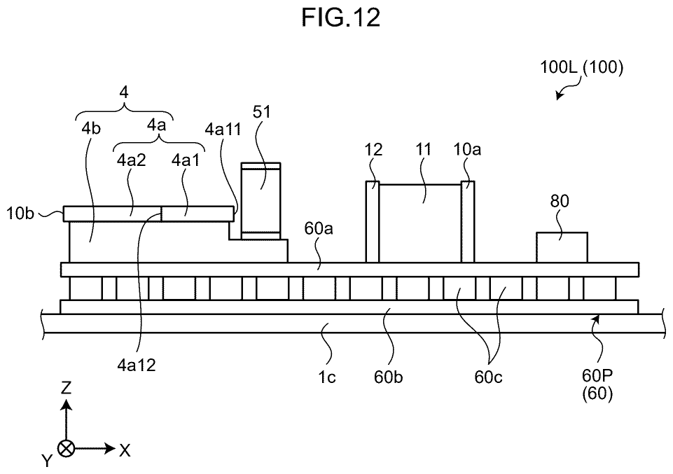

FIG. 12 is a side view of some portion of an optical module 100L (100) according to a 12th embodiment. The optical module 100L according to the 12th embodiment has an identical configuration to the configuration according to the ninth embodiment. Hence, in the 12th embodiment too, it becomes possible to achieve identical effects to the effects achieved according to the ninth embodiment.

However, in the 12th embodiment, the optical module 100L includes a capacitor 80. The capacitor 80 is disposed midway in the conducting route used for supplying the electric power to the heater 12. In that case, the capacitor 80 may function as a noise filter, thereby enabling holding down unintentional time variation of the electric power supplied to the heater 12 and enabling achieving more stability in the operational state of the heater 12. Hence, with such a configuration, the temperature adjustment of the optical filter 11 using the heater 12 may be performed with a greater degree of accuracy.

### 13th and 14th Embodiments

Placement of Heater with Respect to Optical Filter

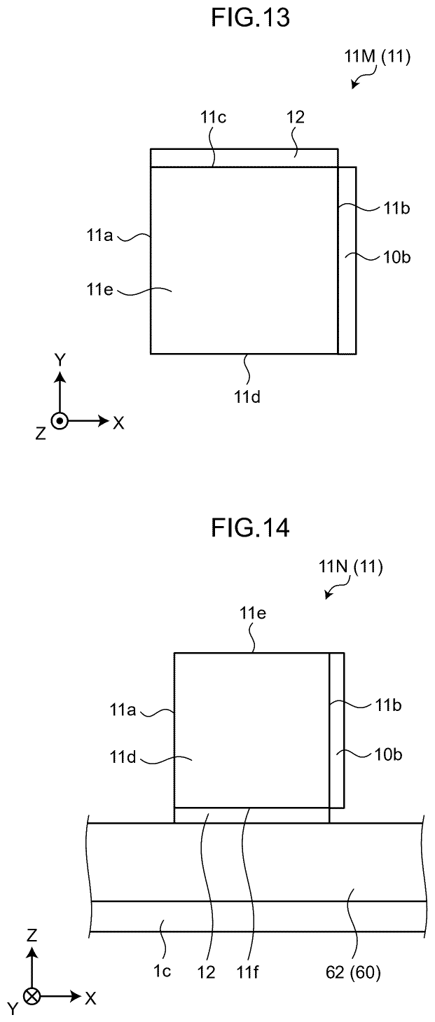

FIG. 13 is a plan view of an optical filter 11M (11) according to a 13th embodiment. FIG. 14 is a side view of an optical filter 11N (11) according to a 14th embodiment. The heater 12 may be disposed on a side surface 11c of the optical filter 11 (see FIG. 13) or on a bottom surface 11f of the optical filter 11 (see FIG. 14). However, those are not the only possible cases. Alternatively, the heater 12 may be disposed on a front surface 11a, or on another side surface 11d, or on a top surface 11e. Moreover, when the mirror 10a is disposed in a different part or a different component than the optical filter 11, the heater 12 may be disposed on a rear surface 11b. The front surface 11a, the rear surface 11b, the side surfaces 11c and 11d, the top surface 11e, and the bottom surface 11f represent examples of an outer surface of the optical filter 11. In this way, if the heater 12 is disposed to cover some portion of an outer surface of the optical filter 11, the temperature adjustment using the heater 12 may be performed with more efficiency or with a greater degree of accuracy.

As explained in the first to 12th embodiments and the 14th embodiment, when the heater 12 is positioned on the optical path, it becomes necessary to manufacture the heater 12 with such a transparent material that the heat producing unit, which produces heat due to the joule heat according to the supplied electric power, and the base member, which supports the heat producing unit, have the light transmittance of, for example, 90 [%] or higher. Such a transparent heat producing unit may be manufactured from, for example, indium tin oxide, tin oxide, titanium dioxide, zinc oxide, carbon nanotube, conductive polymer, silver nanowire, silver, nickel, or silver nanoparticle compounded resin. The transparent base member may be manufactured from, for example, silica glass. Meanwhile, when a transparent material is used, the heater 12 may be covered by an antireflection film.

### 15th to 19th Embodiments

### Configuration of Heater

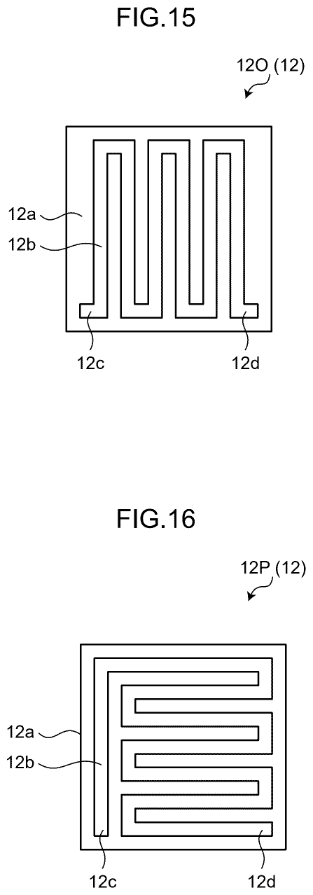

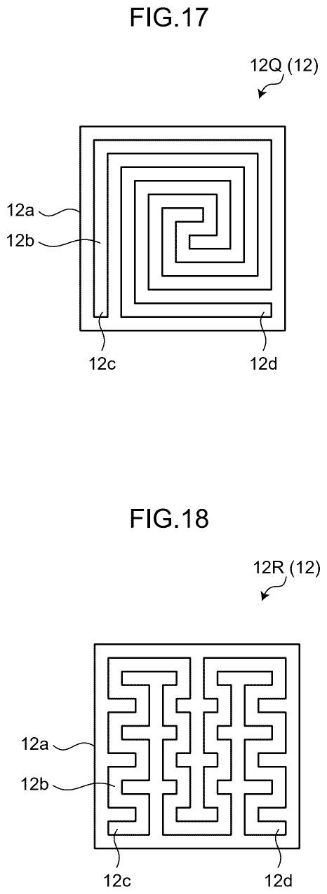

FIGS. 15 to 19 are plan views of heaters 120 to 12S according to 15th to 19th embodiments. As illustrated in FIGS. 15 to 19, the heater 12 includes a base member 12a that either is like a quadrilateral plate or is membranous, and includes a heat producing unit 12b. The heat producing unit 12b is formed in a linear shape that extends while bending between terminals 12c and 12d on the surface of the base member 12a. As illustrated in FIGS. 15 to 19, the heat producing unit 12b may be formed in a variety of patterns. Moreover, instead of partially covering the surface of the base member 12a, the heat producing unit 12b may cover the entire surface of the base member 12a. In that case, the heat producing unit 12b may be manufactured using vapor deposition, or sputtering, or screen printing.

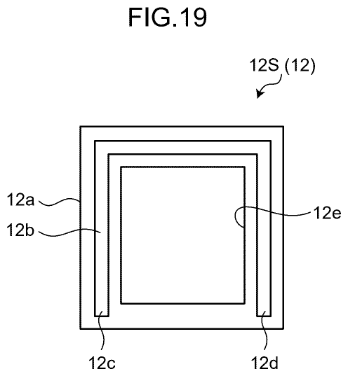

As illustrated in FIG. 19, an opening 12e may be formed on the base member 12a for allowing passage of the light. In that case, the base member 12a may be manufactured from a nontransparent material.

While certain embodiments and modification examples have been described, these embodiments and modification examples have been presented by way of example only, and are not intended to limit the scope of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, shape, size, length, width, thickness, height, number, arrangement, position, material, etc.) may be suitably modified.

According to the present disclosure, for example, it becomes possible to obtain an optical device that enables holding down inconvenient phenomena occurring due to the heat resistance among a plurality of components or occurring due to the heat resistance between a component and a temperature adjustment mechanism.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wavelength-tunable laser comprising:
a light amplifying unit configured to
emit light,
amplify the light, and
output the light from a first end portion and from a second end portion on an opposite side of the first end portion;
a first mirror configured to reflect the light output from the first end portion;
a second mirror configured to reflect the light output from the second end portion;
an optical filter through which the light output from the light amplifying unit passes, the optical filter being disposed in between the light amplifying unit and one of the first mirror or the second mirror and having predetermined wavelength characteristics;
a lens through which light travelling between the light amplifying unit and the optical filter passes, the lens being disposed in between the light amplifying unit and the optical filter; and
a first temperature adjustment unit configured to adjust a temperature of the optical filter.

2. The wavelength-tunable laser according to claim 1, further comprising an optical component configured to vary a direction of travel of the light or a position of travel of the light.

3. The wavelength-tunable laser according to claim 1, wherein, a mirror of the first or second mirror for reflecting the light which has passed through the optical filter is disposed on the optical filter, disposed on a different optical component different than the optical filter or disposed on a component or a part supporting the different optical component.

4. The wavelength-tunable laser according to claim 1, wherein the first temperature adjustment unit includes at least one of a Peltier module or a resistance heating module.

5. The wavelength-tunable laser according to claim 1, further comprising a second temperature adjustment unit configured to adjust a temperature of the light amplifying unit.

6. The wavelength-tunable laser according to claim 5, wherein the second temperature adjustment unit includes a Peltier module.

7. The wavelength-tunable laser according to claim 6, wherein the optical filter is disposed on the Peltier module.

8. The wavelength-tunable laser according to claim 7, further comprising a first heat shielding member disposed in between the optical filter and the Peltier module.

9. The wavelength-tunable laser according to claim 1, wherein the first temperature adjustment unit includes a resistance heating module configured to cover a part of an outer surface of the optical filter.

10. The wavelength-tunable laser according to claim 9, further comprising a capacitor disposed in a conducting route used for supplying electric power to the resistance heating module.

11. The wavelength-tunable laser according to claim 9, wherein the resistance heating module is transparent material.

12. The wavelength-tunable laser according to claim 1, wherein the optical filter is an etalon filter, a DBR filter or a Mach-Zehnder filter.

13. The wavelength-tunable laser according to claim 1, wherein the optical filter includes:
a first optical filter disposed in between the light amplifying unit and the first mirror; and
a second optical filter disposed in between the light amplifying unit and the second mirror.

14. The wavelength-tunable laser according to claim 13, wherein the lens includes:
a first lens disposed in between the light amplifying unit and the first optical filter; and
a second lens disposed in between the light amplifying unit and the second optical filter.

15. An optical device comprising:
the wavelength-tunable laser according to claim 1; and
a housing configured to house the wavelength-tunable laser.
